(19) United States
(12) Patent Application Publication
(10) Pub. No.: US 2024/0113104 A1
(43) Pub. Date: Apr. 4, 2024

(54) FORKSHEET TRANSISTOR STRUCTURES WITH GATE CUT SPINE

(71) Applicant: Intel Corporation, Santa Clara, CA (US)

(72) Inventors: Sukru Yemenicioglu, Portland, OR (US); Leonard P. Guler, Hillsboro, OR (US); Tahir Ghani, Portland, OR (US); Xinning Wang, Hillsboro, OR (US)

(73) Assignee: Intel Corporation, Santa Clara, CA (US)

(21) Appl. No.: 17/936,952

(22) Filed: Sep. 30, 2022

(51) Int. Cl. H01L 27/088; H01L 21/8234; H01L 21/84; H01L 27/092; H01L 27/12

(52) U.S. Cl. CPC H01L 27/088; H01L 21/823481; H01L 21/84; H01L 27/092; H01L 27/1203

(57) ABSTRACT

Techniques are provided to form semiconductor devices that include a gate cut that passes through a plurality of semiconductor bodies (e.g., nanoribbons or nanosheets) such that the gate cut acts as a dielectric spine in a forksheet arrangement with the semiconductor bodies on either side of the gate cut. In an example, two semiconductor devices in a forksheet arrangement include semiconductor bodies directly on either side of a dielectric spine. A gate structure includes a gate dielectric (e.g., high-k gate dielectric material) and a gate electrode (e.g., conductive material such as workfunction material and/or gate fill metal) that extends around each of the semiconductor bodies of both semiconductor devices. The dielectric spine interrupts the entire height of the gate structure between the two devices and includes dielectric material (e.g., low-k dielectric), and the gate dielectric of the gate structure is not present along sidewalls of the spine between adjacent bodies.

### FIELD OF THE DISCLOSURE

The present disclosure relates to integrated circuits, and more particularly, to metal gate cuts made in semiconductor devices.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures used to isolate adjacent transistors becomes challenging. Accordingly, there remain a number of non-trivial challenges with respect to forming semiconductor devices.

### BRIEF DESCRIPTION OF THE DRAWINGS

FIGS. 1A and 1B are cross-sectional and plan views, respectively, of some semiconductor devices that illustrate a gate cut used as a dielectric spine in a forksheet arrangement, in accordance with an embodiment of the present disclosure.

FIGS. 2A-2H″ are cross-sectional views that illustrate various stages in an example process for forming semiconductor devices that have a gate cut used as a dielectric spine in a forksheet arrangement, in accordance with some embodiments of the present disclosure.

FIG. 3 illustrates a cross-sectional view of a chip package containing one or more semiconductor dies, in accordance with some embodiments of the present disclosure.

FIG. 4 is a flowchart of a fabrication process for semiconductor devices having a gate cut used as a dielectric spine in a forksheet arrangement, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include a gate cut that passes through a plurality of semiconductor bodies (e.g., nanosheets or nanoribbon such that the gate cut acts as a dielectric spine in a forksheet arrangement with the semiconductor bodies on either side of the gate cut. In an example, two semiconductor devices in a forksheet arrangement include semiconductor nanoribbons or nanosheets directly on either side of a dielectric spine. The nanoribbons or nanosheets of each device extend from a source region to a drain region. A gate structure includes a gate dielectric (e.g., high-k gate dielectric material) and a gate electrode (e.g., conductive material such as workfunction material and/or gate fill metal) that extends around each of the semiconductor nanoribbons or nanosheets of both semiconductor devices. The dielectric spine interrupts the entire height of the gate structure between the two devices. According to some embodiments, the dielectric spine includes a low-k dielectric material. Furthermore, the dielectric spine may be formed after the formation of the semiconductor nanoribbons or nanosheets and the gate structure, such that the gate dielectric of the gate structure is not present along sidewalls of the dielectric spine between adjacent nanoribbons or nanosheets. Numerous variations and embodiments will be apparent in light of this disclosure.

General Overview

As previously noted above, there remain a number of non-trivial challenges with respect to integrated circuit fabrication. In more detail, the construction of a forksheet transistor relies on a predefined wall generally referred to as a spine. Nanosheets extend laterally outward from two opposing sidewalls of the spine. However, the dielectric spine of forksheet transistors is fabricated early in the process. As such, the spine material must be able to withstand several etch processes and very aggressive chemistries. The insulators that fit these requirements generally include high-k dielectric material (e.g., materials having a dielectric constant higher than silicon oxide or higher than 3.9). Unfortunately, the high-k material of the dielectric spine can cause undesirably high parasitic capacitance.

Thus, and in accordance with an embodiment of the present disclosure, techniques are provided herein to form forksheet transistors having a dielectric spine that is formed as a gate cut to pass through both the metal gate and nanoribbons to separate the two devices. By forming the dielectric spine at the same time as the metal gate cuts (e.g., after formation of the gate structures), the previous material limitations for the dielectric spine no longer apply. For example, low-k dielectric materials (e.g., materials having a dielectric constant equal to or lower than silicon oxide, or equal to or lower than 3.9) may be used for the dielectric spine, thus lowering parasitic capacitance. In some embodiments, gate cuts and the dielectric spine are formed at the same time with the same dielectric material.

Since the dielectric spine of the forksheet arrangement is formed after the formation of the nanoribbons or nanosheets and the gate structure, it is structurally distinct from dielectric spines that are formed before the formation of such structures. For instance, in an example of the present disclosure, the gate dielectric of the gate structure does not extend up any of the sidewalls of the dielectric spine between adjacent nanosheets. In another example, the dielectric material of the dielectric spine includes low-k materials, although it may include high-k materials as well. In yet another example, the dielectric spine is formed via lithographic alignment, thus giving rise to some translation error, which results in the nanoribbons or nanosheets on one side of the dielectric spine having a greater width (e.g., at least 10% greater) than the nanoribbons or nanosheets on the opposite side of the dielectric spine. For purpose of clarity, and in the context of a forksheet transistor structure, note that: nanoribbon width generally refers to the distance that a given nanoribbon extends horizontally outward from the spine; nanoribbon height of a given nanoribbon generally refers to the distance that a given nanoribbon extends vertically along the sidewall of the spine; and nanoribbon length of a given nanoribbon generally refers to the distance that a given nanoribbon extends horizontally along the sidewall of the spine.

According to an embodiment, an integrated circuit includes a first semiconductor device having a first plurality of semiconductor nanoribbons (or nanosheets, used interchangeably herein) extending between a first source region and a first drain region and a first gate dielectric on one or more surfaces of the first plurality of semiconductor nanoribbons, a second semiconductor device having a second plurality of semiconductor nanoribbons extending between a second source region and a second drain region and a second gate dielectric on one or more surfaces of the second plurality of semiconductor nanoribbons, and a dielectric spine between the first plurality of semiconductor nanoribbons and the second plurality of semiconductor nanoribbons. The dielectric spine contacts both the first plurality of semiconductor nanoribbons and the second plurality of semiconductor nanoribbons. The first gate dielectric is not on at least a portion of a first sidewall of the dielectric spine between adjacent ones of the first plurality of semiconductor nanoribbons. The second gate dielectric is not on at least a portion of a second sidewall of the dielectric spine between adjacent ones of the second plurality of semiconductor nanoribbons.

According to another embodiment, an integrated circuit includes a spine comprising dielectric material, and first and second sets of semiconductor bodies extending laterally therefrom. In more detail, the first set includes two or more semiconductor bodies each laterally extending from a first side of the spine, and the second set includes two or more semiconductor bodies each laterally extending from a second side of the spine. A first gate structure is on the two or more semiconductor bodies of the first set, and includes a first gate electrode and a first gate dielectric, the first gate dielectric between the two or more semiconductor bodies of the first set and the first gate electrode. The first gate electrode is directly on the first side of the spine between adjacent semiconductor bodies of the first set. Similarly, a second gate structure is on the two or more semiconductor bodies of the second set, the second gate structure including a second gate electrode and a second gate dielectric, the second gate dielectric between the two or more semiconductor bodies of the second set and the second gate electrode. The second gate electrode is directly on the second side of the spine between adjacent semiconductor bodies of the second set. In a conventional forksheet device, there would be gate dielectric between the spine and the gate electrode, rather than the gate electrode being directly on the spine.

According to another embodiment, an integrated circuit includes a first semiconductor device having a first plurality of semiconductor nanoribbons extending in a first direction between a first source region and a first drain region, a second semiconductor device having a second plurality of semiconductor nanoribbons extending in the first direction between a second source region and a second drain region, and a dielectric spine between the first plurality of semiconductor nanoribbons and the second plurality of semiconductor nanoribbons. The dielectric spine contacts both the first plurality of semiconductor nanoribbons and the second plurality of semiconductor nanoribbons. A width of the first plurality of semiconductor nanoribbons in a second direction differs from a width of the second plurality of semiconductor nanoribbons in the second direction by 10% or more. The degree of asymmetry can vary from one example to the next, and may be done intentionally (e.g., to adjust transistor performance), or unintentionally (e.g., due to mask alignment error). The second direction is substantially orthogonal to the first direction (e.g., within zero to five degrees of 90 degree orthogonality).

According to another embodiment, a method of forming an integrated circuit includes forming a multilayer fin extending lengthwise in a first direction, the multilayer fin including first material layers alternating with second material layers, the second material layers comprising a semiconductor material suitable for use as a nanoribbon channel; forming a sacrificial layer and spacers on sidewall s of the sacrificial layer, the sacrificial layer and spacers extending over the multilayer fin in a second direction different form the first direction; removing portions of the multilayer fin not protected beneath the sacrificial layer and spacers; forming source and drain regions at exposed ends of the multilayer fin; removing the sacrificial layer and the first material layers of the fin to form suspended second material layers; forming a gate structure around the suspended second material layers; etching a trench through the second material layers and the gate structure around the second material layers; and forming a dielectric spine within the trench, such that the dielectric spine separates portions of the second material layers from each other.

The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a dielectric spine in a forksheet arrangement that does not have any gate dielectric extending up sidewalls of the dielectric spine between nanoribbons or nanosheets. In another example, such tools may be used to identify difference in the widths of the nanoribbons on either side of the dielectric spine in the forksheet arrangement, such as a difference in width of 2 nm or more, or other asymmetry that would be atypical of a conventional process.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

Architecture

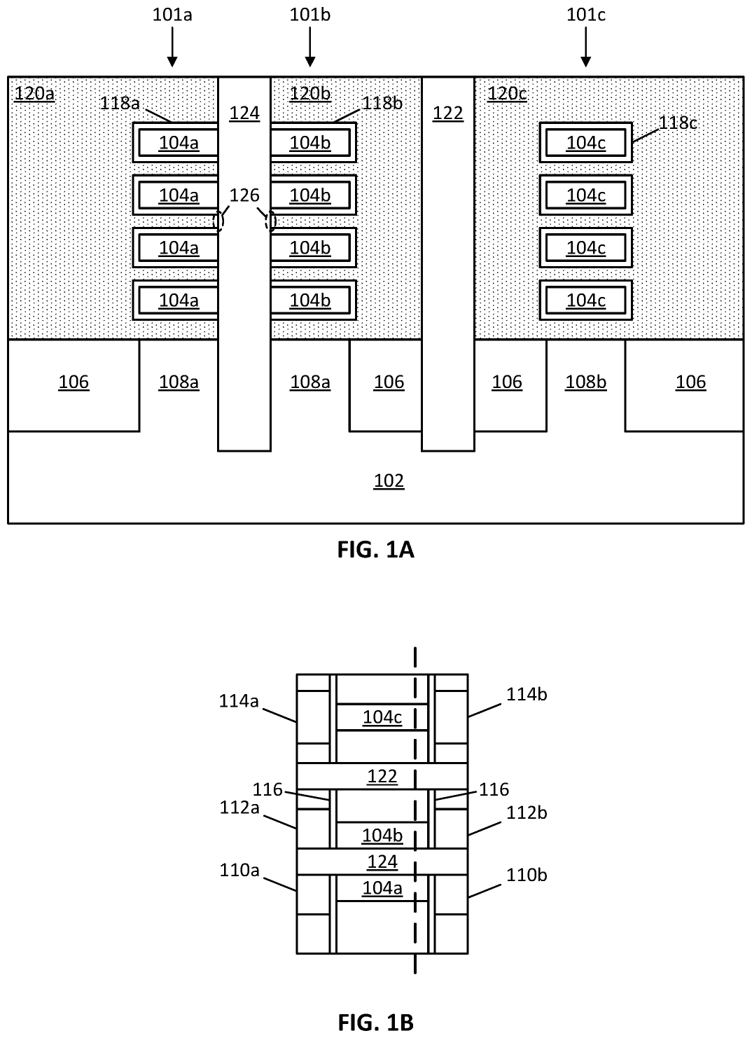

FIG. 1A is a cross sectional view taken across two example semiconductor devices 101a and 101b in a forksheet arrangement, and a third semiconductor device 101c, according to an embodiment of the present disclosure. FIG. 1B is a top-down view of the semiconductor devices 101a-101c where FIG. 1A illustrates the cross section taken across the dashed line. It should be noted that some of the material layers (such as gate electrode 120a, 120b, and 120c) in the top-down view of FIG. 1B have been omitted for clarity. Each of semiconductor devices 101a and 101b may include nanoribbons or nanosheets having one side that contacts dielectric spine 124. Semiconductor device 101c may include nanoribbons or nanowires in a gate-all-around (GAA) structure. The various illustrated semiconductor devices represent a portion of an integrated circuit that may contain any number of similar semiconductor devices.

As can be seen, semiconductor devices 101a-101c are formed on a substrate 102. Any number of semiconductor devices can be formed on substrate 102. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of (or all of) substrate 102 is removed and replaced with one or more backside interconnect layers to form backside signal and power routing.

Each of semiconductor devices 101a-101c includes one or more nanoribbons 104a-101c, respectively, that extend parallel to one another along a direction between a source region and a drain region (e.g., a first direction into and out of the page in the cross-section view of FIG. 1A). Although the term nanoribbons is used here for each of semiconductor devices 101a-101c for convenience, the term is not intended to limit the shape of the semiconductor regions. Any of the semiconductor regions could be more rounded (closer to nanowires) or the semiconductor regions of semiconductor devices 101a and 101b in the forksheet arrangement could be called nanosheets. More generally, the term nanoribbon may also encompass other similar shapes such as nanowires or nanosheets. The semiconductor material of nanoribbons 104a-104c may be formed from substrate 102. In some embodiments, semiconductor devices 101a-101c may each include fins of alternating layers of material (e.g., alternating layers of silicon and SiGe) that facilitates forming of the illustrated nanoribbons 104a-104c during a gate forming process where one type of the alternating layers is selectively etched away so as to liberate the other type of alternating layers within the channel region. Again, the alternating layers can be blanket deposited and then etched into fins or deposited into fin-shaped trenches.

As can further be seen, semiconductor devices may be separated by a dielectric fill 106 that can include silicon oxide. Dielectric fill 106 provides shallow trench isolation (STI) between adjacent semiconductor devices. Dielectric fill 106 can be any suitable dielectric material, such as silicon dioxide, aluminum oxide, or silicon oxycarbonitride.

Semiconductor devices 101a-101c each include a corresponding subfin region 108a-108c. According to some embodiments, subfin region 108a-108c comprises the same semiconductor material as substrate 102 and is adjacent to dielectric fill 106.

According to some embodiments, nanoribbons 104a-104c (or other semiconductor bodies) extend between a source and a drain region in the first direction to provide an active region for a transistor (e.g., the semiconductor region beneath the gate). The source and drain regions are not shown in the cross-section of FIG. 1A, but are seen in the top-down view of FIG. 1B where nanoribbons 104a extend between a first source region 110a and a first drain region 110b, nanoribbons 104b extend between a second source region 112a and a second drain region 112b, and nanoribbons 104c extend between a third source region 114a and a third drain region 114b. FIG. 1B also illustrates spacer structures 116 that extend around the ends of nanoribbons 104a-104c and along sidewalls of the gate structures between spacer structures 116. Spacer structures 116 may include a dielectric material, such as silicon nitride.

According to some embodiments, the source and drain regions are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. In an example, for instance, one transistor is a p-type MOS (PMOS) transistor, and the other transistor is an n-type MOS (NMOS) transistor. Any number of source and drain configurations and materials can be used.

According to some embodiments, a first gate structure extends over nanoribbons 104a of semiconductor device 101a along a second direction across the page, a second gate structure extends over nanoribbons 104b of semiconductor device 101b along the second direction, and a third gate structure extends over nanoribbons 104c of semiconductor device 101c along the second direction. Each gate structure includes a respective gate dielectric 118a-118c and a gate layer (or gate electrode) 120a-120c. Gate dielectric 118a-118c represents any number of dielectric layers present between nanoribbons 104a-104c and gate electrode 120a-120c. Gate dielectric 118a-118c may also be present on the surfaces of other structures within the gate trench, such as on subfin regions 108a-108c. Gate dielectric 118a-118c may include any suitable gate dielectric material(s). In some embodiments, gate dielectric 118a-118c includes a layer of native oxide material (e.g., silicon oxide) on the nanoribbons or other semiconductor regions making up the channel region of the devices, and a layer of high-k dielectric material (e.g., hafnium oxide) on the native oxide.

Gate electrode 120a-120c may represent any number of conductive layers, such as any metal, metal alloy, or doped polysilicon layers. In some embodiments, gate electrode 120a-120c includes one or more workfunction metals around nanoribbons 104a-104c. In some embodiments, one or both of semiconductor devices 101a and 101b is a p-channel device that include a workfunction metal having titanium around its nanoribbons and semiconductor device 101c is an n-channel device that includes a workfunction metal having tungsten around its nanoribbons. Gate electrode 120a-120c may also include a fill metal or other conductive material around the workfunction metals to provide the whole gate electrode structure.

According to some embodiments, adjacent devices may be separated along the second direction (e.g., across the page) by a gate cut 122, which acts like a dielectric barrier between gate structures. Gate cut 122 may be formed from a sufficiently insulating material, such as a dielectric material. Example materials for gate cut 122 include silicon nitride, silicon oxide, or silicon oxynitride. In some embodiments, gate cut 122 includes more than one dielectric material, such as a dielectric layer at its edges and a separate dielectric fill. The dielectric layer may include a high-k dielectric material and the dielectric fill may include a low-k dielectric material. Gate cut 122 extends through an entire height of the gate structures on either side of gate cut 122 and extends into at least a portion of dielectric fill 106. In some embodiments, gate cut 122 extends into a portion of the underlying substrate 102.

According to some embodiments, a dielectric spine 124 separates first semiconductor device 101a from second semiconductor device 101b in a forksheet arrangement. Dielectric spine 124 may include the same dielectric material or dielectric structure as gate cut 122. Accordingly, dielectric spine 124 may include a low-k dielectric material, such as silicon oxide, in some embodiments. In some such embodiments, dielectric spine 124 includes a dielectric layer at its edges and a separate dielectric fill. The dielectric layer may include a high-k dielectric material and the dielectric fill may include a low-k dielectric material. In some embodiments, the dielectric constant of the entire dielectric spine 124 (including all dielectric material layers) is less than about 8.0.

According to some embodiments, dielectric spine 124 is formed after the formation of the gate structures (such that dielectric spine 124 is formed through the gate structures, like gate cut 122). Thus, sidewall portions 126 of dielectric spine between adjacent nanoribbons 104a on the left side of spine 124, or between adjacent nanoribbons 104b on the right side of spine 124, do not have gate dielectric 118a or 118b, respectively, on them, as highlighted with the dashed circles.

Gate cut 122 also extends in the first direction as seen in FIG. 1B such that it cuts across at least the entire width of the gate trench. According to some embodiments, gate cut 122 also extends further past spacer structures 116. In some examples, gate cut 122 extends across more than one gate trench in the first direction (e.g., cutting through more than one gate structure running parallel along the second direction).

Similarly, dielectric spine 124 may continue in the first direction past spacer structures 116 such that dielectric spine 124 also cuts through epitaxial source and drain regions. For instance, and with further reference to the example of FIG. 1B, dielectric spine 124 may split a first epitaxial region into first source region 110a and second source region 112a and may split a second epitaxial region into first drain region 110b and second drain region 112b. Any source region can also act as a drain region and vice versa based on how the regions are connected in the circuit.

Fabrication Methodology

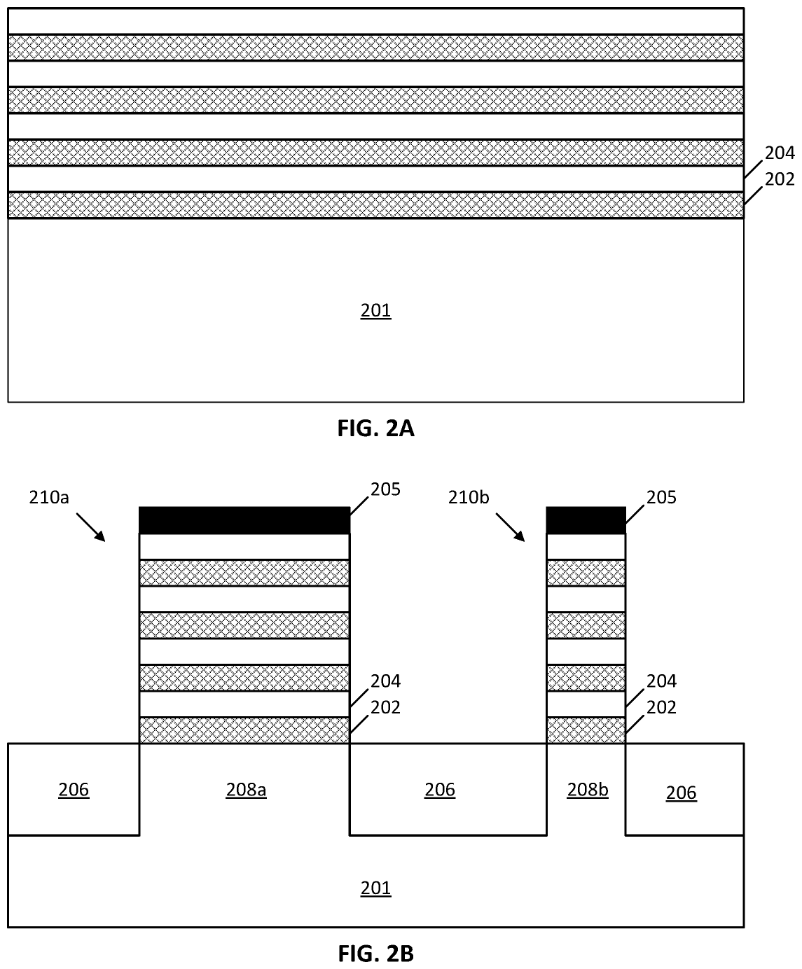

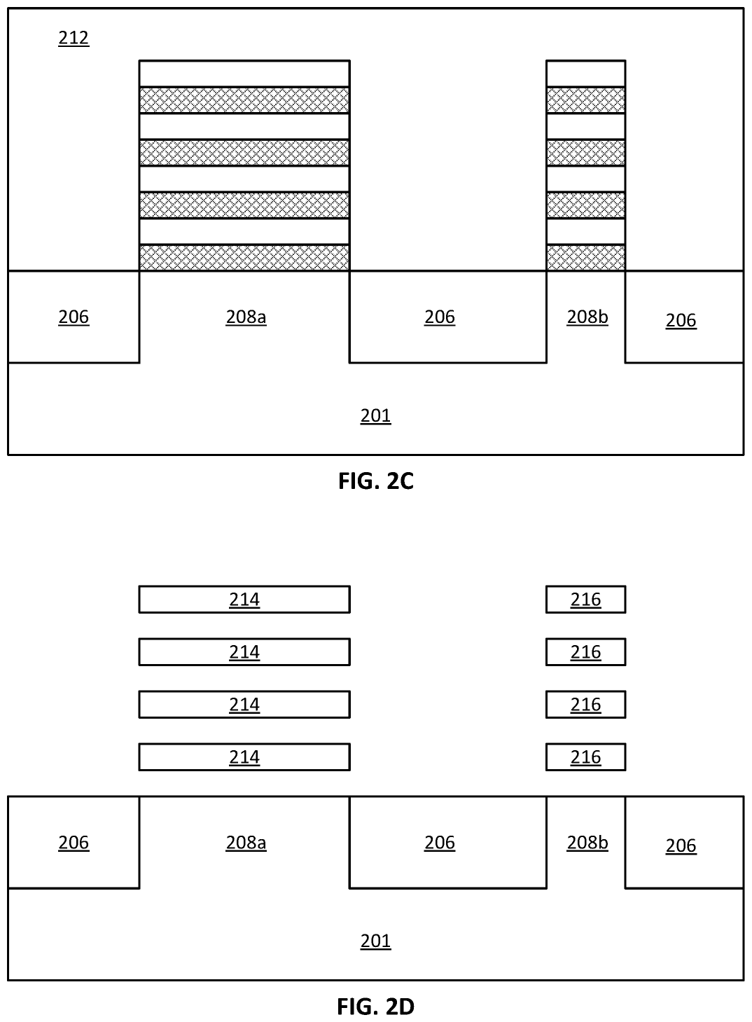

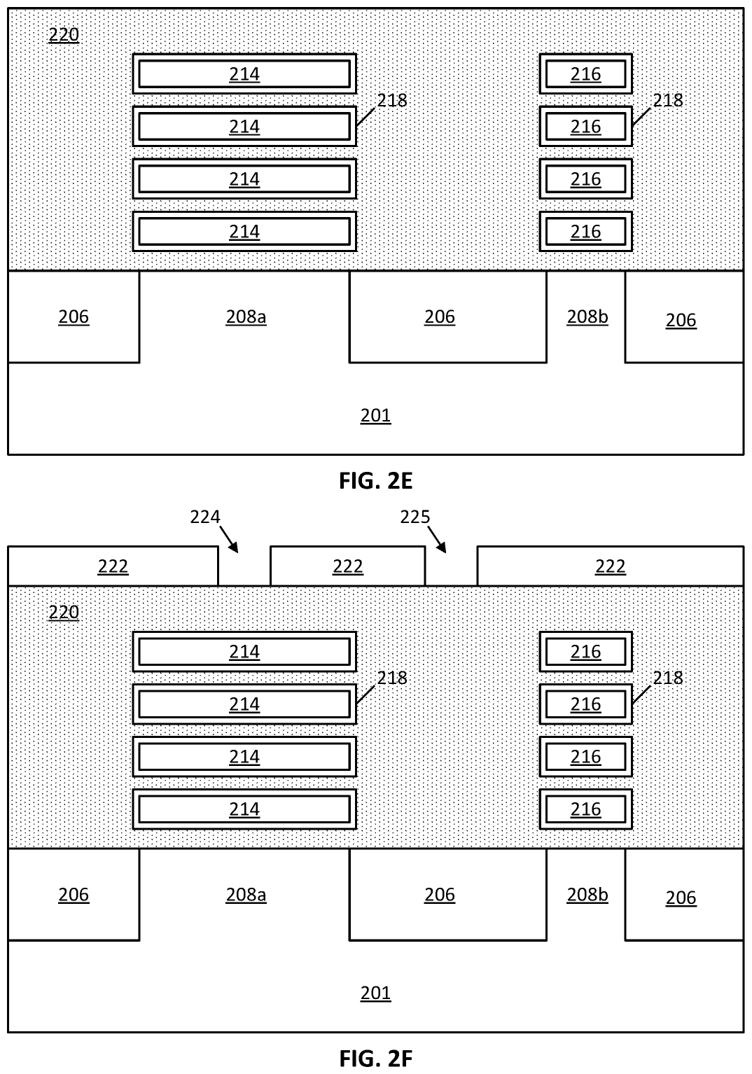

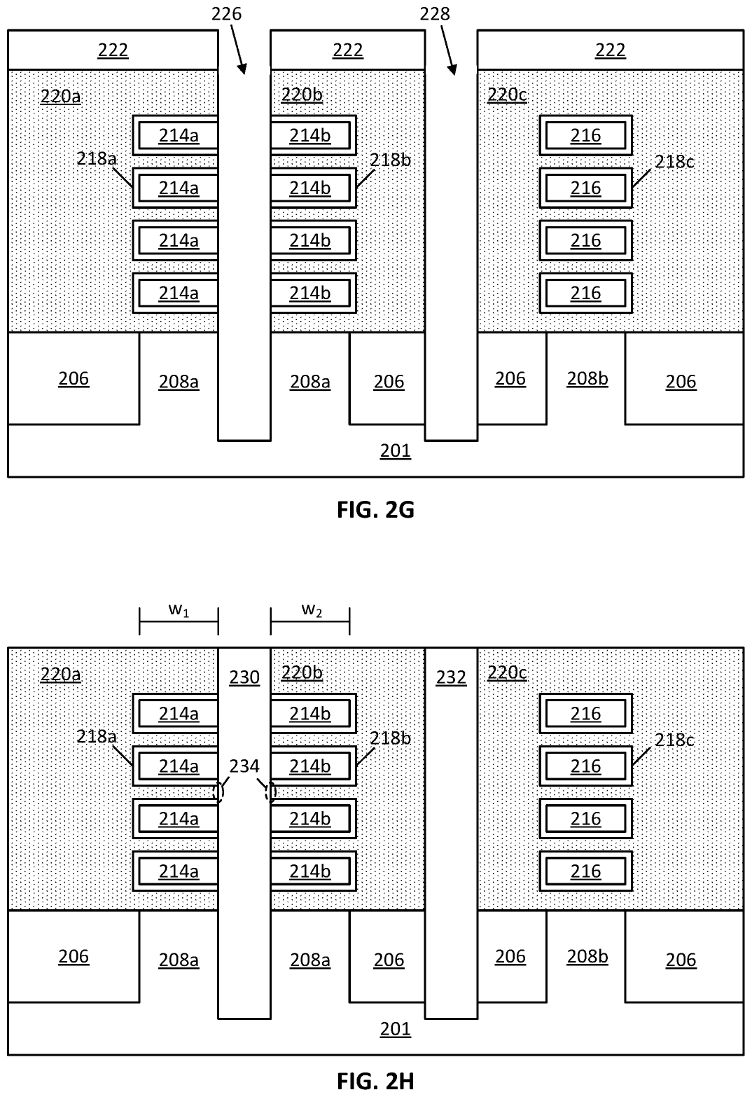

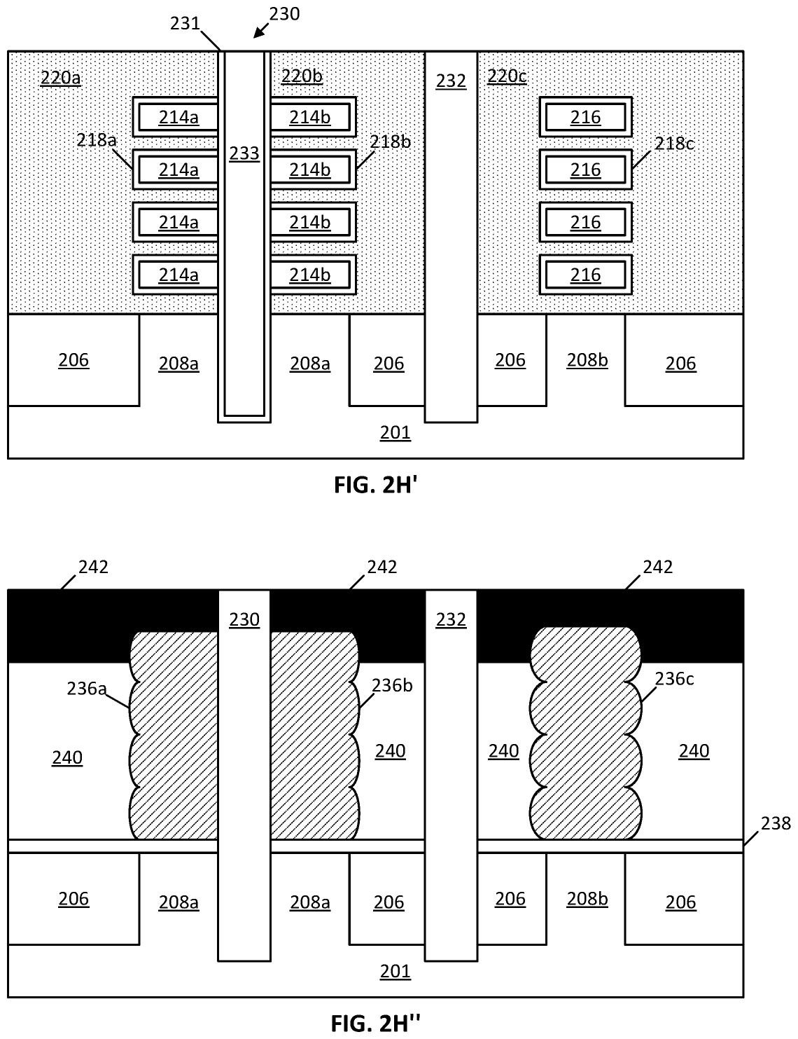

FIGS. 2A-2H″ include cross-sectional views that collectively illustrate an example process for forming an integrated circuit with semiconductor devices and a gate cut used as a dielectric spine in a forksheet arrangement, in accordance with an embodiment of the present disclosure. Each figure shows an example structure that results from the process flow up to that point in time, so the depicted structure evolves as the process flow continues, culminating in the structure shown in FIG. 2H, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated. Although the fabrication of a single forksheet arrangement is illustrated in the aforementioned figures, it should be understood that any number of similar forksheet arrangements can be fabricated across the integrated circuit using the same processes discussed herein.

FIG. 2A illustrates a cross-sectional view taken through a substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

FIG. 2B depicts the cross-section view of the structure shown in FIG. 2A following the formation of a cap layer 205 and the subsequent formation of fins 210a and 210b beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. The rows of fins 210a and 210b extend lengthwise in a first direction (e.g., into and out of the page).

According to some embodiments, an anisotropic etching process through the layer stack continues into at least a portion of substrate 201. The etched portion of substrate 201 may be filled with a dielectric fill 206 that acts as shallow trench isolation (STI) between adjacent fins. Dielectric fill 206 may be any suitable dielectric material such as silicon oxide. Subfin regions 208a and 208b represent remaining portions of substrate 201 between dielectric fill 206 beneath fin 210a and fin 210b, respectively, according to some embodiments.

Fin 210a is wider along the second direction (e.g., across the page) compared to fin 210b, according to some embodiments. In some examples, fin 210a is at least 2.5×, at least 3.0×, at least 3.5×, or at least 4.0× times wider than fin 210b. According to some embodiments, fin 210a will ultimately be used to form a forksheet structure with two adjacent devices.

FIG. 2C depicts the cross-section view of the structure shown in FIG. 2B following the formation of a sacrificial gate 212 extending across the fins in a second direction different from the first direction, according to some embodiments. Sacrificial gate 212 may extend across the fins in a second direction that is orthogonal to the first direction. According to some embodiments, the sacrificial gate material is formed in parallel strips across the integrated circuit and removed in all areas not protected by a gate masking layer. Sacrificial gate 212 may be any suitable material that can be selectively removed without damaging the semiconductor material of the fins. In some examples, sacrificial gate 212 includes polysilicon.

Following the formation of sacrificial gate 212 (and prior to replacement of sacrificial gate 212 with a metal gate), additional semiconductor device structures are formed that are not shown in these cross-sections. These additional structures include spacer structures on the sidewalls of sacrificial gate 212 and source and drain regions on either ends of each of the fins.

FIG. 2D depicts the cross-section view of the structure shown in FIG. 2C following the removal of sacrificial gate 212 and the removal of sacrificial layers 202, according to some embodiments. In examples where any gate masking layers are still present, they would also be removed at this time. Once sacrificial gate 212 is removed, the fins that had been beneath sacrificial gate 212 are exposed.

In the example where the fins include alternating semiconductor layers, sacrificial layers 202 are selectively removed from fin 210a to release nanoribbons 214 that extend between corresponding source or drain regions, and sacrificial layers 202 are selectively removed from fin 210b to release nanoribbons 216 that extend between corresponding source or drain regions. It should be understood that nanoribbons 216 may also be nanowires. Sacrificial gate 212 and sacrificial layers 202 may be removed using the same isotropic etching process or different isotropic etching processes.

FIG. 2E depicts the cross-section view of the structure shown in FIG. 2D following the formation of a gate structure and subsequent polishing, according to some embodiments. The gate structure includes a gate dielectric 218 and a conductive gate electrode 220. Gate dielectric 218 may be first formed around nanoribbons 214 and 216 prior to the formation of gate electrode 220. The gate dielectric 218 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 218 includes a layer of hafnium oxide with a thickness between about 1 nm and about 5 nm. In some embodiments, gate dielectric 218 may include one or more silicates (e.g., titanium silicate, tungsten silicate, niobium silicate, and silicates of other transition metals). In some cases, gate dielectric 218 may include a first layer on nanoribbons 214 and 216, and a second layer on the first layer. The first layer can be, for instance, an oxide of the semiconductor material of nanoribbons 214 and 216 (e.g., silicon dioxide) and the second layer can be a high-k dielectric material (e.g., hafnium oxide). More generally, gate dielectric 218 can include any number of dielectric layers. According to some embodiments, gate dielectric 218 forms along all surfaces exposed within the gate trench, such as along inner sidewalls of the spacer structures and along the top surfaces of dielectric fill 206 and subfin regions 208a and 208b.

As noted above, gate electrode 220 can represent any number of conductive layers. The conductive gate electrode 220 may be deposited using electroplating, electroless plating, CVD, PECVD, ALD, or PVD, to name a few examples. In some embodiments, gate electrode 220 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 220 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure, the entire structure may be polished such that the top surface of the gate structure (e.g., top surface of gate electrode 220) is planar with the top surface of other semiconductor elements, such as the spacer structures that define the gate trench.

FIG. 2F illustrates another cross-section view of the structure shown in FIG. 2E following the formation of a masking structure 222, according to some embodiments. Masking structure 222 may include any number of hard mask layers, such as any dielectric layers or carbon hard mask layers. A first opening 224 may be formed through masking structure 222 to expose a portion of gate electrode 220 that is above nanoribbons 214 where a dielectric spine will be formed. A second opening 225 may be formed through masking structure 222 to expose a portion of gate electrode 220 where a gate cut will be formed. A reactive ion etching (RIE) process may be used to form first opening 224 and second opening 225.

According to some embodiments, first opening 224 may not be aligned directly in the center of nanoribbons 214 along the second direction due to translation error during lithography. As such, the resulting dielectric spine beneath first opening 224 may not be aligned directly in the center of nanoribbons 214, as will be discussed in more detail herein. More generally, the level of symmetry of the nanoribbons to either side of the spine may vary from one example to the next. In some cases, there will be asymmetry, such that the nanoribbons to one side of the spine are longer than the nanoribbons to the other side of the spine.

FIG. 2G illustrates another cross-section view of the structure shown in FIG. 2F following the formation of a spine recess 226 and a gate cut recess 228 through at least an entire height of the gate structure, according to an embodiment. Spine recess 226 and gate cut recess 228 may be formed together using an anisotropic metal gate etch process that iteratively etches through portions of gate electrode 220 while simultaneously protecting the sidewalls of the recess from lateral etching to provide a high height-to-width aspect ratio (e.g., aspect ratio of 5:1 or higher, or 10:1 or higher). Gate cut recess 228 may extend into at least a portion of dielectric fill 206 or even deeper into a portion of the underlying substrate 201. Spine recess 226 may extend into a portion of subfin region 208a or even deeper into underlying substrate 201. In some examples, the height of spine recess 226 is within 10% of the height of the gate cut recess 228. In some such cases, the height of spine recess 226 is within 10 nm, or 5 nm, or 2 nm, of the height of the gate cut recess 228. Having similar heights may be beneficial (e.g., avoid backside processing issues that manifest when one such recess is much deeper than another such recess).

According to some embodiments, the formation of spine recess 226 and gate cut recess 228 segments gate electrode 220 into isolated gate electrodes 220a-220c. Similarly, gate dielectric 218 has been identified as separate gate dielectrics 218a-218c corresponding to gate electrodes 220a-220c. Gate electrode 220a and gate dielectric 218a may be identified as part of a first gate structure, gate electrode 220b and gate dielectric 218b may be identified as part of a second gate structure, and gate electrode 220c and gate dielectric 218c may be identified as part of a third gate structure.

According to some embodiments, spine recess 226 cuts through nanoribbons 214 and gate dielectric 218 around nanoribbons 214, such that portions of nanoribbons 214a and 214b are exposed along the sidewalls of spine recess 226, and portions of gate dielectric 218a and gate dielectric 218b are exposed along the sidewalls of spine recess 226. Additionally, portions of both gate electrode 220a and gate electrode 220b are exposed along the sidewalls of spine recess 226.

FIG. 2H illustrates another cross-section view of the structure shown in FIG. 2G following the formation of a dielectric spine 230 within spine recess 226 and a gate cut within gate cut recess 228, and the removal of masking structure 222 and any passivation layers used during the formation of spine recess 226 and gate cut recess 228, according to some embodiments. Each of dielectric spine 230 and gate cut 232 may be formed from one or more dielectric materials. For example, both dielectric spine 230 and gate cut 232 may include only silicon oxide or only silicon nitride. More generally, both dielectric spine 230 and gate cut 232 may include the same low-k dielectric material (e.g., porous silicon oxide, or carbon-doped silicon oxide have a carbon concentration in the range of about 8% to 16%). In other embodiments, dielectric spine 230 includes an airgap or any number of voids to lower the overall dielectric constant of dielectric spine 230. In the case of an airgap, the spine may include one or more gasses (e.g., oxygen, nitrogen) or be devoid of gas. Also, in the case of an airgap, a capping layer deposited over the recess may partially deposit within the upper portion of the recess. Dielectric spine 230 may have a width extending from one sidewall to an opposite sidewall between nanoribbons 214a and 214b that is between about 10 nm and about 20 nm.

In some examples, both dielectric spine 230 and gate cut 232 include the same first dielectric layer at their respective edges and a same dielectric fill within the remaining volume. FIG. 2H′ illustrates an example of dielectric spine 230 having a dielectric layer 231 at edges of dielectric spine 230 and a fill dielectric 233. Dielectric layer 231 may include a high-k dielectric material (e.g. materials with a dielectric constant higher than that of silicon oxide or higher than 3.9, such as those examples listed with respect to gate dielectric 218) while dielectric fill 233 may include a low-k dielectric material (e.g. materials with a dielectric constant equal to or lower than that of silicon oxide, or equal to or lower than 3.9). In some examples, the dielectric constant of the entire dielectric spine 230 (including dielectric layer 231 and fill dielectric 233) is less than about 8.0. In this structure, dielectric layer 231 directly contacts portions of both nanoribbons 214a and nanoribbons 214b.

According to some embodiments, gate dielectric 218a and gate dielectric 218b are not on sidewall portions 234 of dielectric spine 230 between adjacent pairs of nanoribbons 214a and 214b, as depicted with the dashed circles. This is due to the fact that dielectric spine 230 is formed after the formation of gate dielectric 218 around nanoribbons 214 as collectively shown in FIGS. 2E-G. Similarly, gate electrode 220a and 220b on either side of dielectric spine 230 directly contact sidewall portions 234 of dielectric spine due to the lack of any gate dielectric between them. Note that dielectric material deposited within the spine recess 226 (e.g., including any low-k and high-k materials deposited therein) can be distinguished from gate dielectric materials that would normally be on sidewalls of spine 234. So, for instance, a high-k dielectric material in layer 231 may be the same high-k dielectric material used in the gate dielectric. To this end, dielectric material within recess 226 or otherwise apart of spine 234 is not to be confused with the gate dielectric structure 218.

As noted above, and with further reference to FIG. 2H, the alignment of dielectric spine 230 may not be directly in the middle of nanoribbons 214, such that a first width w₁ of nanoribbons 214a is different from a second width w₂ of nanoribbons 214b, thus providing a degree of asymmetry. In some embodiments, first width w₁ differs from second width w₂ by 5%, or 10%, or 15%, or 20%. More generally, the first width w₁ may differ from second width w₂ by a non-trivial amount that would otherwise be atypical of a conventional forksheet fabrication process, such as the example case where left side nanoribbons are 4 nm or 5 nm or more wider than the right side nanoribbons, or vice-versa.

Dielectric spine 230 extends in the first direction (e.g., into and out of the page) through the gate trench and also cutting through the source and drain regions to split those regions into separate source and drain regions for each of nanoribbons 214a and nanoribbons 214b. FIG. 2H″ illustrates a cross-section view of the structure from FIG. 2H, but taken across the source/drain region as opposed to the gate trench. Accordingly, both dielectric spine 230 and gate cut 232 are seen extending in the first direction through the source/drain region. Dielectric spine 230 extends directly between a first source or drain region 236a and a second source or drain region 236b. A third source or drain region 236c is also present on an opposite side of gate cut 232. According to some embodiments, a lower dielectric layer 238 exists beneath source or drain regions 236a-236c. Lower dielectric layer 238 can include any suitable dielectric material, such as silicon oxide or silicon nitride and may be provided to isolate source or drain regions 236a-236c from subfin regions 208a and 208b. According to some embodiments, another dielectric fill 240 is provided around and over portions of source or drain regions 236a-236c along the source/drain trench. Dielectric fill 240 may be any suitable dielectric material, although in some embodiments, dielectric fill 240 includes the same dielectric material as dielectric fill 206 or lower dielectric layer 238. In one example, each of dielectric fill 240, lower dielectric layer 238, and dielectric fill 206 includes silicon oxide. According to some embodiments, one or more conductive contacts 242 are present on or over one or more corresponding source or drain regions 236a-236c. Conductive contacts 242 may be any suitably conductive material such as tungsten (W). Other conductive materials may include copper (Cu), ruthenium (Ru), cobalt (Co), titanium (Ti), molybdenum (Mo), or any alloys thereof. Contacts 242 may include multiple layers, such as a silicide (e.g., tungsten silicide) and a fill metal (e.g., tungsten).

According to some embodiments, both first source or drain region 236a and second source or drain region 236b contact respective sidewalls of dielectric spine 230 along an entire height of each of first source or drain region 236a and second source or drain region 236b. In another example, a top surface of first source or drain region 236a and a top surface of second source or drain region 236b may be substantially co-planar (e.g., the surface plane of one is within 1 or 2 nm of the surface plane of the other). In another example, no voids are present within first source or drain region 236a and second source or drain region 236b at or near the sidewalls of dielectric spine 230. These structural features may occur due to the bifurcation of the source or drain region by dielectric spine 230.

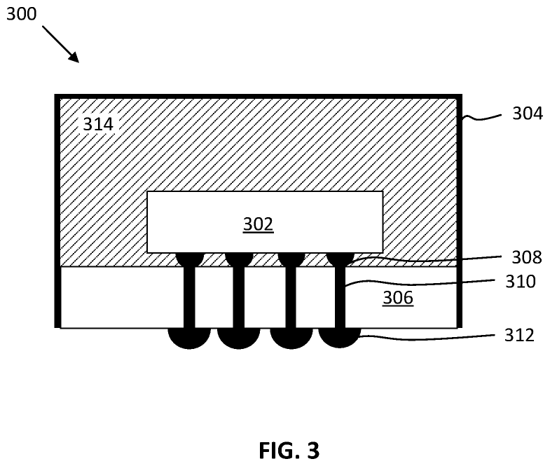

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

Methodology

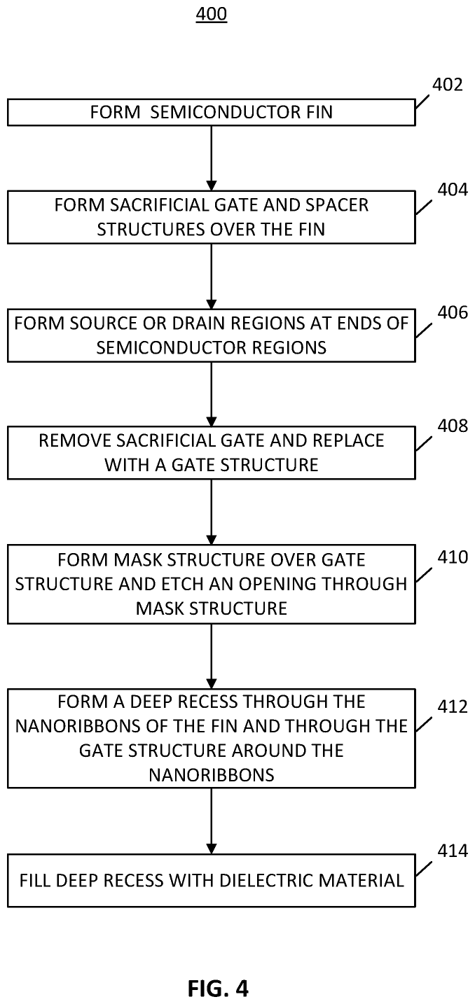

FIG. 4 is a flow chart of a method 400 for forming at least a portion of an integrated circuit, according to an embodiment. Various operations of method 400 may be illustrated in FIGS. 2A-2H. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe all processes that are performed to form common transistor structures. Some of the operations of method 400 may be performed in a different order than the illustrated order.

Method 400 begins with operation 402 where a semiconductor fin is formed, according to some embodiments. The fin can be formed of material deposited onto an underlying substrate. In one such example case, the fin includes alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The fin may also include a cap structure that is used to define the location of the fin during, for example, an RIE process. The cap structure may be a dielectric material, such as silicon nitride.

According to some embodiments, a dielectric fill is formed around a subfin portion of the fin. In some embodiments, the dielectric fill extends between the fin and any other adjacent parallel fins and runs lengthwise in the same direction as the fin. In some embodiments, the anisotropic etching process that forms the fin also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon oxide.

Method 400 continues with operation 404 where a sacrificial gate and spacer structures are formed over the fin. The sacrificial gate may be patterned using a gate masking layer in a strip that runs orthogonally over the fin (many gate masking layers and corresponding sacrificial gates may be formed parallel to one another (e.g., forming a cross-hatch pattern with multiple fins). The gate masking layer may be any suitable hard mask material, such as CHM or silicon nitride. The sacrificial gate may be formed from any suitable material that can be selectively removed at a later time without damaging the semiconductor material of the fin. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 400 continues with operation 406 where source or drain regions are formed at the ends of the semiconductor region of the fin. Any portions of the fin not protected by the sacrificial gate and spacer structures may be removed using, for example, an anisotropic etching process followed by the epitaxial growth of the source or drain regions from the exposed ends of the semiconductor layers in the fin. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 400 continues with operation 408 where the sacrificial gate is removed and replaced with a gate structure. The sacrificial gate may be removed using an isotropic etching process that selectively removes all of the material from the sacrificial gate, thus exposing the fin between the set of spacer structures. Any sacrificial layers within the exposed fin between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples.

Method 400 continues with operation 410 where a mask structure is formed over the gate structure and an opening is formed through the mask structure to expose a portion of the underlying gate electrode. According to some embodiments, the opening through the mask structure is at a location where a dielectric spine is to be formed through a portion of the nanoribbons to form a forksheet structure. In some examples, the opening is at or near a mid-point along a width of the nanoribbons. The mask structure may include any number of hard mask layers, such as any dielectric layers or carbon hard mask layers. The opening may be formed using a directional RIE process.

Method 400 continues with operation 412 where a deep recess is formed through the gate structure and through the nanoribbons beneath the opening through the mask structure. According to some embodiments, the deep recess has a high height-to-width aspect ratio of at least 5:1 and extends through at least an entire thickness of the gate electrode. In some examples, the deep recess extends into the subfin region beneath the nanoribbons or into the underlying substrate. According to some embodiments, portions of the nanoribbons are exposed along the sidewalls of the deep recess.

Method 400 continues with operation 414 where the deep recess is filled with a dielectric material to form a dielectric spine through the nanoribbons. The dielectric spine isolates two semiconductor devices on either side of the dielectric spine in a forksheet structure. According to some embodiments, the dielectric spine may include only silicon oxide or silicon nitride, or any dielectric material having a dielectric constant equal to or lower than 3.9. In some examples, the dielectric spine includes a first dielectric layer at the edges and a dielectric fill within a remaining volume. The first dielectric layer may include a high-k dielectric material (e.g. materials with a dielectric constant higher than that of silicon oxide or higher than 3.9) while the dielectric fill may include a low-k dielectric material (e.g. materials with a dielectric constant equal to or lower than that of silicon oxide or equal to or lower than 3.9).

Example System

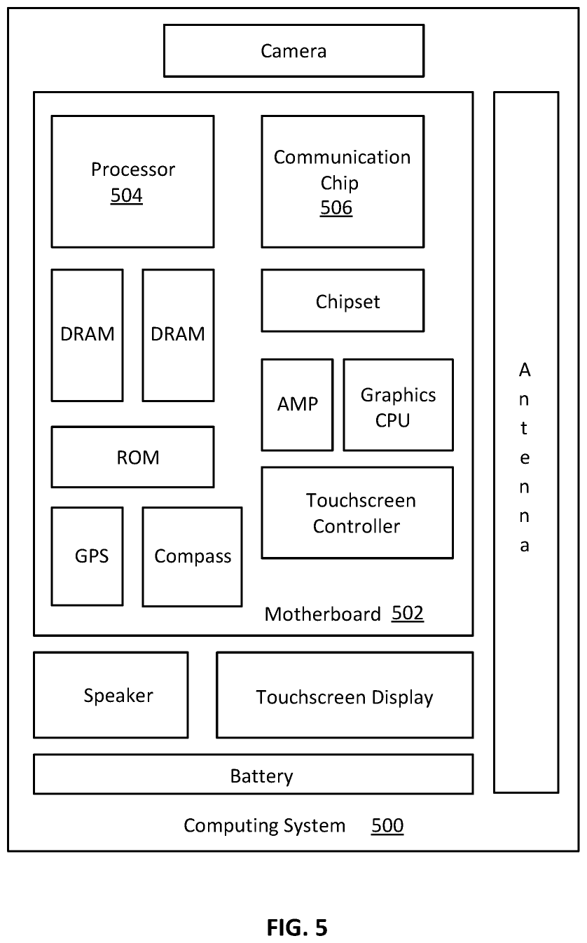

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment, such as a module including an integrated circuit on a substrate, the substrate having semiconductor devices that have a gate cut used as a dielectric spine in a forksheet arrangement. In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having first and second semiconductor bodies each extending between a first source region and a first drain region, and a first gate dielectric wrapped around each of the first and second semiconductor bodies, a second semiconductor device having third and fourth semiconductor bodies each extending between a second source region and a second drain region, and a second gate dielectric wrapped around each of the third and fourth semiconductor bodies, and a dielectric spine between the first semiconductor device and the second semiconductor device, such that the dielectric spine contacts both the first and second semiconductor bodies and both the third and fourth semiconductor bodies. The first gate dielectric is not on a portion of a first sidewall of the dielectric spine between the first and second semiconductor bodies, and the second gate dielectric is not on a portion of a second sidewall of the dielectric spine between the third and fourth semiconductor bodies.

Example 2 includes the integrated circuit of Example 1, wherein each of the first, second, third, and fourth semiconductor bodies is a nanoribbon or nanosheet, each of the nanoribbons or nanosheets comprising germanium, silicon, or both.

Example 3 includes the integrated circuit of Example 1 or 2, wherein the dielectric spine comprises a dielectric material having a dielectric constant equal to or lower than 3.9.

Example 4 includes the integrated circuit of any one of Examples 1-3, wherein the dielectric spine has a width extending between the first and second sidewalls of the dielectric spine, the first and second semiconductor bodies extending outward from the first side, and the third and fourth semiconductor bodies extending outward from the second side, the width being in the range of about 10 nm to about 20 nm.

Example 5 includes the integrated circuit of any one of Examples 1-4, wherein the first semiconductor device comprises a first gate electrode on the first gate dielectric and the second semiconductor device comprises a second gate electrode on the second gate dielectric.

Example 6 includes the integrated circuit of Example 5, further comprising a gate cut through a portion of the first gate electrode or a portion of the second gate electrode, the gate cut comprising a dielectric material.

Example 7 includes the integrated circuit of Example 6, wherein the dielectric material of the gate cut and the dielectric material of the dielectric spine is the same dielectric material.

Example 8 includes the integrated circuit of Example 5 or 6, wherein the first gate electrode is on the portion of the first sidewall of the dielectric spine between the first and second semiconductor bodies where there is no first gate dielectric, and wherein the second gate electrode is on the portion of the second sidewall of the dielectric spine between the third and fourth semiconductor bodies where there is no second gate dielectric.

Example 9 includes the integrated circuit of any one of Examples 1-8, wherein the dielectric spine comprises a first layer of dielectric material that contacts both the first and second semiconductor bodies and the third and fourth semiconductor bodies, and a second layer or body of dielectric material on the first layer of dielectric material.

Example 10 includes the integrated circuit of Example 9, wherein the first layer of dielectric material comprises a high-k dielectric material and the second layer or body of dielectric material comprises a low-k dielectric material.

Example 11 includes the integrated circuit of any one of Examples 1-10, wherein the dielectric spine further extends between the first drain region and the second drain region, and between the first source region and the second source region.

Example 12 includes the integrated circuit of Example 11, wherein the first drain region and the second drain region each contact respective sidewalls of the dielectric spine along an entire height of the first drain region and the second drain region, and wherein the first source region and the second source region each contact respective sidewalls of the dielectric spine along an entire height of the first source region and the second source region.

Example 13 includes the integrated circuit of any one of Examples 1-12, wherein the dielectric spine comprises one or more dielectric materials having a total dielectric constant equal to or lower than 8.

Example 14 is a printed circuit board comprising the integrated circuit of any one of Examples 1-13.

Example 15 is an electronic device that includes a chip package comprising one or more dies, at least one of the one or more dies including the integrated circuit of any one of Examples 1-13.

Example 16 includes the electronic device of Example 15, further comprising a printed circuit board, wherein the chip package is attached to the printed circuit board.

Example 17 is a method of forming an integrated circuit. The method includes forming a multilayer fin extending lengthwise in a first direction, the multilayer fin including first material layers alternating with second material layers, the second material layers comprising a semiconductor material suitable for use as a nanoribbon channel; forming a sacrificial layer and spacers on sidewalls of the sacrificial layer, the sacrificial layer and spacers extending over the multilayer fin in a second direction different form the first direction; removing portions of the multilayer fin not protected beneath the sacrificial layer and spacers; forming source and drain regions at exposed ends of the multilayer fin; removing the sacrificial layer and the first material layers of the fin to form suspended second material layers; forming a gate structure around the suspended second material layers; etching a trench through the second material layers and the gate structure around the second material layers; and forming a dielectric spine within the trench, such that the dielectric spine separates portions of the second material layers from each other.

Example 18 includes the method of Example 17, wherein forming the dielectric spine comprises forming a dielectric material having a dielectric constant less than or equal to 3.9.

Example 19 includes the method of Example 17 or 18, wherein forming the dielectric spine comprises forming a first dielectric layer having a material with a dielectric constant greater than 3.9; and forming a second dielectric layer having a material with a dielectric constant less than or equal to 3.9.

Example 20 includes the method of any one of Examples 17-19, wherein the trench is a first trench and the method further comprises etching a second trench through a portion of the gate structure and not through any of the second material layers; and forming a gate cut within the second trench. The gate cut comprises a dielectric material.

Example 21 includes the method of Example 20, wherein etching the first trench and etching the second trench occur at the same time.

Example 22 is an integrated circuit that includes a spine comprising dielectric material, a first set of two or more semiconductor bodies each laterally extending from a first side of the spine, a second set of two or more semiconductor bodies each laterally extending from a second side of the spine, a first gate structure on the two or more semiconductor bodies of the first set, and a second gate structure on the two or more semiconductor bodies of the second set. The first gate structure includes a first gate electrode and a first gate dielectric. The first gate dielectric is between the two or more semiconductor bodies of the first set and the first gate electrode. The first gate electrode is directly on the first side of the spine between adjacent semiconductor bodies of the first set. The second gate structure includes a second gate electrode and a second gate dielectric. The second gate dielectric is between the two or more semiconductor bodies of the second set and the second gate electrode. The second gate electrode is directly on the second side of the spine between adjacent semiconductor bodies of the second set.

Example 23 includes the integrated circuit of Example 22, wherein the first set of one or more semiconductor bodies and the first gate structure are part of a p-type metal oxide semiconductor (PMOS) transistor structure, and the second set of one or more semiconductor bodies and the second gate structure are part of an n-type metal oxide semiconductor (NMOS) transistor structure.

Example 24 includes the integrated circuit of Example 23, wherein the PMOS transistor structure and the NMOS transistor structure are part of a forksheet device.

Example 25 includes the integrated circuit of any one of Examples 23-24, comprising a first source region and a first drain region, each in contact with the first set of two or more semiconductor bodies, such that the first set of two or more semiconductor bodies is between the first source region and the first drain region, and a second source region and a second drain region, each in contact with the second set of two or more semiconductor bodies, such that the second set of two or more semiconductor bodies is between the second source region and the second drain region.

Example 26 includes the integrated circuit of any one of Examples 22-25, wherein the first and second gate dielectrics each includes multiple layers.

Example 27 includes the integrated circuit of any one of Examples 22-26, wherein the first and second gate electrodes each includes multiple layers.

Example 28 includes the integrated circuit of any one of Examples 22-27, wherein the spine includes multiple layers.

Example 29 is an integrated circuit that includes a first semiconductor device having a first plurality of semiconductor nanoribbons extending in a first direction between a first source region and a first drain region, a second semiconductor device having a second plurality of semiconductor nanoribbons extending in the first direction between a second source region and a second drain region, and a dielectric spine between the first plurality of semiconductor nanoribbons and the second plurality of semiconductor nanoribbons, such that the dielectric spine contacts both the first plurality of semiconductor nanoribbons and the second plurality of semiconductor nanoribbons. A width of the first plurality of semiconductor nanoribbons in a second direction differs from a width of the second plurality of semiconductor nanoribbons in the second direction by at least 10%. The second direction is substantially orthogonal to the first direction.

Example 30 includes the integrated circuit of Example 29, wherein the first plurality of semiconductor nanoribbons and the second plurality of semiconductor nanoribbons comprise germanium, silicon, or both.

Example 31 includes the integrated circuit of Example 29 or 30, wherein the dielectric spine comprises a low-k dielectric material having a dielectric constant equal to or lower than 3.9.

Example 32 includes the integrated circuit of any one of Examples 29-31, wherein the dielectric spine has a width extending between the first plurality of semiconductor nanoribbons and the second plurality of semiconductor nanoribbons of about 10 nm to about 20 nm.

Example 33 includes the integrated circuit of any one of Examples 29-32, wherein the dielectric spine comprises a first layer of dielectric material that contacts both the first plurality of semiconductor nanoribbons and the second plurality of semiconductor nanoribbons, and a second layer of dielectric material on the first layer of dielectric material.

Example 34 includes the integrated circuit of Example 33, wherein the first layer of dielectric material comprises a high-k dielectric material and the second layer of dielectric material comprises a low-k dielectric material.

Example 35 includes the integrated circuit of any one of Examples 29-34, wherein the dielectric spine further extends between the first drain region and the second drain region, and between the first source region and the second source region.

Example 36 includes the integrated circuit of Example 35, wherein the first drain region and the second drain region each contact respective sidewalls of the dielectric spine along an entire height of the first drain region and the second drain region, and wherein the first source region and the second source region each contact respective sidewalls of the dielectric spine along an entire height of the first source region and the second source region.

Example 37 is a printed circuit board comprising the integrated circuit of any one of Examples 29-36.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having first and second semiconductor bodies each extending between a first source region and a first drain region, and a first gate dielectric wrapped around each of the first and second semiconductor bodies;
a second semiconductor device having third and fourth semiconductor bodies each extending between a second source region and a second drain region, and a second gate dielectric wrapped around each of the third and fourth semiconductor bodies; and
a dielectric spine between the first semiconductor device and the second semiconductor device, such that the dielectric spine contacts both the first and second semiconductor bodies and both the third and fourth semiconductor bodies;
wherein the first gate dielectric is not on a portion of a first sidewall of the dielectric spine between the first and second semiconductor bodies, and wherein the second gate dielectric is not on a portion of a second sidewall of the dielectric spine between the third and fourth semiconductor bodies.

2. The integrated circuit of claim 1, wherein the first semiconductor device comprises a first gate electrode on the first gate dielectric and the second semiconductor device comprises a second gate electrode on the second gate dielectric.

3. The integrated circuit of claim 2, further comprising a gate cut through a portion of the first gate electrode or a portion of the second gate electrode, the gate cut comprising a dielectric material that is the same as the dielectric material of the dielectric spine.

4. The integrated circuit of claim 3, wherein the first gate electrode is on the portion of the first sidewall of the dielectric spine between the first and second semiconductor bodies where there is no first gate dielectric, and wherein the second gate electrode is on the portion of the second sidewall of the dielectric spine between the third and fourth semiconductor bodies where there is no second gate dielectric.

5. The integrated circuit of claim 1, wherein the dielectric spine further extends between the first drain region and the second drain region, and between the first source region and the second source region.

6. The integrated circuit of claim 5, wherein the first drain region and the second drain region each contact respective sidewalls of the dielectric spine along an entire height of the first drain region and the second drain region, and wherein the first source region and the second source region each contact respective sidewalls of the dielectric spine along an entire height of the first source region and the second source region.

7. A printed circuit board comprising the integrated circuit of claim 1.

8. An integrated circuit comprising:
a spine comprising dielectric material;
a first set of two or more semiconductor bodies each laterally extending from a first side of the spine;
a second set of two or more semiconductor bodies each laterally extending from a second side of the spine;
a first gate structure on the two or more semiconductor bodies of the first set, the first gate structure including a first gate electrode and a first gate dielectric, the first gate dielectric between the two or more semiconductor bodies of the first set and the first gate electrode, and the first gate electrode directly on the first side of the spine between adjacent semiconductor bodies of the first set; and
a second gate structure on the two or more semiconductor bodies of the second set, the second gate structure including a second gate electrode and a second gate dielectric, the second gate dielectric between the two or more semiconductor bodies of the second set and the second gate electrode, and the second gate electrode directly on the second side of the spine between adjacent semiconductor bodies of the second set.

9. The integrated circuit of claim 8, wherein the first set of one or more semiconductor bodies and the first gate structure are part of a p-type metal oxide semiconductor (PMOS) transistor structure, and the second set of one or more semiconductor bodies and the second gate structure are part of an n-type metal oxide semiconductor (NMOS) transistor structure.

10. The integrated circuit of claim 9, wherein the PMOS transistor structure and the NMOS transistor structure are part of a forksheet device.

11. The integrated circuit of claim 8, comprising:
a first source region and a first drain region, each in contact with the first set of two or more semiconductor bodies, such that the first set of two or more semiconductor bodies is between the first source region and the first drain region; and
a second source region and a second drain region, each in contact with the second set of two or more semiconductor bodies, such that the second set of two or more semiconductor bodies is between the second source region and the second drain region.

12. The integrated circuit of claim 8, wherein the spine includes at least two different material layers.

13. An integrated circuit comprising:
a first semiconductor device having a first plurality of semiconductor nanoribbons extending in a first direction between a first source region and a first drain region;
a second semiconductor device having a second plurality of semiconductor nanoribbons extending in the first direction between a second source region and a second drain region; and
a dielectric spine between the first plurality of semiconductor nanoribbons and the second plurality of semiconductor nanoribbons, such that the dielectric spine contacts both the first plurality of semiconductor nanoribbons and the second plurality of semiconductor nanoribbons, and wherein a width of the first plurality of semiconductor nanoribbons in a second direction differs from a width of the second plurality of semiconductor nanoribbons in the second direction by at least 10%, the second direction being substantially orthogonal to the first direction.

14. The integrated circuit of claim 13, wherein the first plurality of semiconductor nanoribbons and the second plurality of semiconductor nanoribbons comprise germanium, silicon, or both.

15. The integrated circuit of claim 13, wherein the dielectric spine has a width extending between the first plurality of semiconductor nanoribbons and the second plurality of semiconductor nanoribbons of about 10 nm to about 20 nm.

16. The integrated circuit of claim 13, wherein the dielectric spine comprises a first layer of dielectric material that contacts both the first plurality of semiconductor nanoribbons and the second plurality of semiconductor nanoribbons, and a second layer of dielectric material on the first layer of dielectric material.

17. The integrated circuit of claim 16, wherein the first layer of dielectric material comprises a high-k dielectric material and the second layer of dielectric material comprises a low-k dielectric material.

18. The integrated circuit of claim 13, wherein the dielectric spine further extends between the first drain region and the second drain region, and between the first source region and the second source region.

19. The integrated circuit of claim 18, wherein the first drain region and the second drain region each contact respective sidewalls of the dielectric spine along an entire height of the first drain region and the second drain region, and wherein the first source region and the second source region each contact respective sidewalls of the dielectric spine along an entire height of the first source region and the second source region.

20. A printed circuit board comprising the integrated circuit of claim 13.
